(19) United States
(12) Patent Application Publication
(10) Pub. No.: US 2025/0199081 A1
(43) Pub. Date: Jun. 19, 2025

(54) METHOD AND APPARATUS FOR CALIBRATING BATTERY MEASUREMENT DATA

(71) Applicant: MONA INC., Jeollabuk-do (KR)

(72) Inventor: Chang Hee SONG, Seoul (KR)

(73) Assignee: MONA INC., Jeollabuk-do (KR)

(21) Appl. No.: 18/835,994

(22) PCT Filed: Sep. 14, 2023
(86) PCT No.: PCT/KR2023/013851

§ 371 Date: Aug. 5, 2024

(30) Foreign Application Priority Data
Sep. 21, 2022 (KR) 10-2022-0119516

(51) Int. Cl. G01R 31/389; G01R 31/367; G01R 31/396

(52) U.S. Cl. CPC G01R 31/389; G01R 31/367; G01R 31/396

(57) ABSTRACT

Disclosed are a method and an apparatus for calibrating battery measurement data. The apparatus for calibrating battery measurement data measures alternating current resistances of the same battery sample by using a plurality of different measuring devices, sets, as a reference alternating current resistance, an alternating current resistance measured by a measuring device set as a reference measuring device from among the plurality of measuring devices, determines a first deviation between the reference alternating current resistance and each alternating current resistance measured by the other measuring devices, and calibrates the alternating current resistances measured by the other measuring devices using the first deviation.

### TECHNICAL FIELD

An embodiment of the present disclosure relates to a method and an apparatus for calibrating battery measurement data, and more particularly, to a method and an apparatus for calibrating a deviation between battery measurement data measured by different measuring devices.

The present disclosure is supported by the Future Vehicle Tuning Parts Technology Development Project of the Ministry of Trade, Industry and Energy (Task Number: P0018425, Project Identification Number: 1415187492) and the Small and Medium Business Industry-Academia-Research Cooperation Project of the Ministry of SMEs and Startups (Task Number: S3312750, Project Identification Number: 1425170271).

### BACKGROUND ART

Batteries are used in various fields, such as electric vehicles and energy storage systems (ESS). Since rechargeable batteries (e.g., secondary batteries) deteriorate due to various factors, such as usage cycle or usage environment, it is necessary to check the status of batteries, for example, to determine when to replace the batteries. To check the status of batteries, various values, such as voltage, resistance, and remaining charge of batteries, may be measured using measuring devices. However, battery measurement results may differ for each measuring device due to various factors, such as unique characteristics of the measuring devices, the length and shape of wires, and contact resistance.

### DISCLOSURE

### Technical Problem

To solve the technical problem, embodiments of the present disclosure provide a method and an apparatus for calibrating a deviation in battery measurement data between measuring devices.

### Technical Solution

To achieve the technical solution, an example of a method of calibrating battery measurement data according to an embodiment of the present disclosure includes measuring alternating current resistances of the same battery sample by using a plurality of different measuring devices, setting, as a reference alternating current resistance, an alternating current resistance measured by a measuring device set as a reference measuring device from among the plurality of measuring devices, and determining a first deviation between the reference alternating current resistance and each alternating current resistance measured by the other measuring devices, and storing the first deviation to calibrate alternating current resistances of battery cells measured by the other measuring devices.

To achieve the technical solution, an example of an apparatus for calibrating battery measurement data according to an embodiment of the present disclosure includes a sample measurement unit configured to measure alternating current resistances of the same battery sample by using a plurality of different measuring devices, a deviation determination unit configured to set, as a reference alternating current resistance, an alternating current resistance measured by a measuring device set as a reference measuring device from among the plurality of measuring devices, and determine a first deviation between the reference alternating current resistance and each alternating current resistance measured by the other measuring devices, and a calibration unit configured to calibrate the alternating current resistances of battery cells measured by the other measuring devices using the first deviation.

### Advantageous Effects

According to an embodiment of the present disclosure, a measurement deviation between battery measuring devices may be calibrated. As a deviation in measurement data between measuring devices is calibrated and stored, the calibrated data may be used as learning data to improve the performance of artificial intelligence models or big data analysis results.

### DESCRIPTION OF DRAWINGS

FIG. 1 is a diagram showing an example of an apparatus for calibrating battery measurement data according to an embodiment of the present disclosure;

FIG. 2 is a diagram showing a deviation in alternating current resistance between measuring devices according to an embodiment of the present disclosure;

FIG. 3 is a diagram showing an example of a method of calibrating a deviation in alternating current resistance between measuring devices according to an embodiment of the present disclosure;

FIG. 4 is a diagram showing an example of a method of calibrating a deviation in alternating current resistance between measuring devices for each cycle according to an embodiment of the present disclosure;

FIG. 5 is a diagram showing an example of a user interface for calibrating a deviation between battery measurement data according to an embodiment of the present disclosure;

FIG. 6 is a flowchart showing an example of a method of calibrating battery measurement data according to an embodiment of the present disclosure; and

FIG. 7 is a diagram showing the configuration of an example of an apparatus for calibrating battery measurement data according to an embodiment of the present disclosure.

### BEST MODE

### Mode for Invention

Hereinafter, a method and an apparatus for calibrating battery measurement data according to an embodiment of the present disclosure are described in detail with reference to the attached drawings.

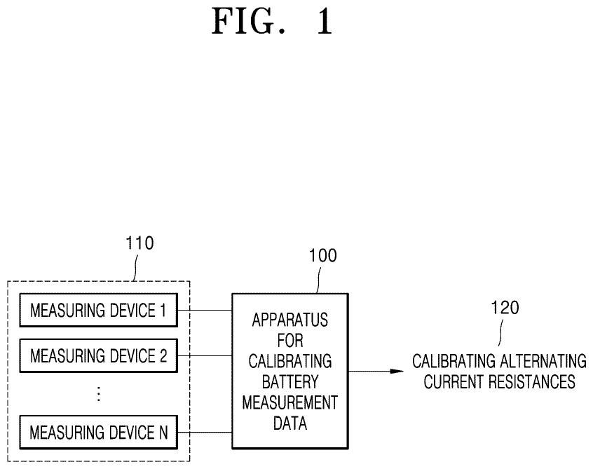

FIG. 1 is a diagram showing an example of an apparatus for calibrating battery measurement data according to an embodiment of the present disclosure.

Referring to FIG. 1, an apparatus for calibrating battery measurement data 100 (hereinafter referred to as “calibrating apparatus”) receives battery measurement data from each of a plurality of measuring devices 110. The measuring devices 110 are devices for measuring various values, such as voltage, current, and resistance of batteries, and various conventional measuring devices may be applied to this embodiment. In an embodiment, the measuring devices 110 may measure battery cells of batteries.

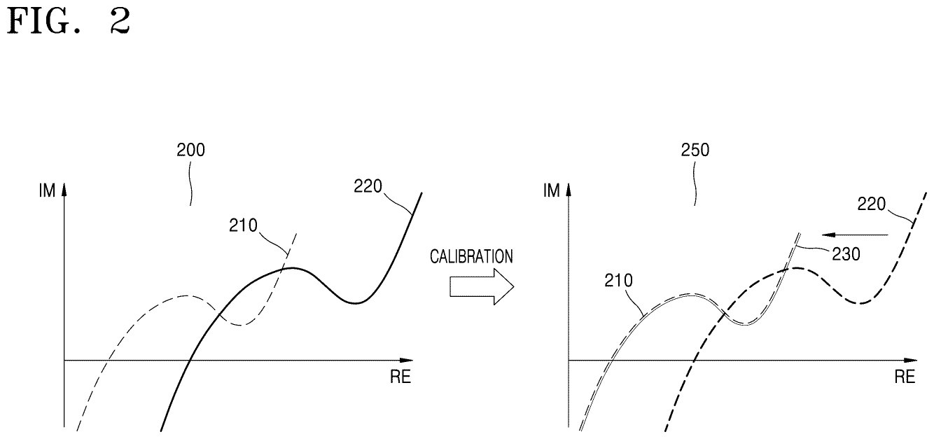

The results of measuring the same battery may differ depending on various factors, such as the unique characteristics of each measuring device 110, the length and shape of wires, and contact resistance. For example, as shown in FIG. 2, alternating current resistances measured by applying an alternating current voltage to a battery may be different for each measuring device 110. In addition, a deviation between various measurement data may be seen between various measuring devices. However, for convenience of explanation, hereinafter, the calibrating apparatus 100 is described on the assumption that the alternating current resistances of the battery measured by the measuring devices 110 are calibrated 120.

FIG. 2 is a diagram showing a deviation in alternating current resistance between measuring devices according to an embodiment of the present disclosure.

Referring to FIG. 2, a graph is shown on a complex plane by connecting the alternating current resistance values for each frequency measured for the same battery by using first and second measuring devices. For example, the alternating current resistances of the battery may be measured by changing the frequency of the alternating current voltage at regular intervals in a certain frequency band and applying the same to the battery. Various conventional methods of measuring alternating current resistances may be applied to this embodiment.

The left FIG. 200 is a graph before calibration, and the right FIG. 250 is a graph after calibration. The first measuring device and the second measuring device measure the alternating current resistances of the same battery. As a result, the overall shape of the left and right FIGS. 200 and 250 is similar, but there is a deviation between the alternating current resistances for each frequency. Therefore, a process of calibrating the deviation (i.e., moving from 220 to 230) is necessary to match an alternating current resistance 220 measured by the second measuring device with an alternating current resistance 210 measured by the first measuring device.

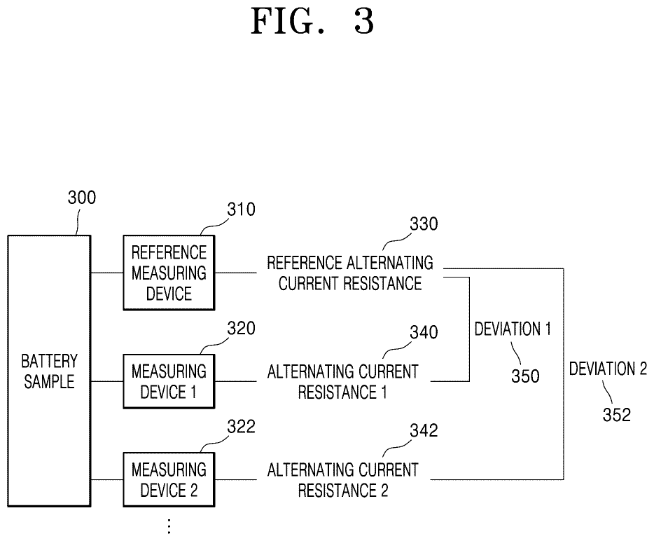

When using the battery's alternating current resistances in big data or artificial intelligence models, a deviation between measuring devices results in reduced performance of artificial intelligence model training or big data analysis. The alternating current resistances obtained by measuring the same battery cell must always be constant to improve the results of analysis and training, regardless of measuring devices. Accordingly, the calibrating apparatus 100 performs a process of calibrating a deviation between alternating current resistances using a method shown in FIG. 3 and below.

FIG. 3 is a diagram showing an example of a method of calibrating a deviation in alternating current resistance between measuring devices according to an embodiment of the present disclosure.

Referring to FIG. 3, the alternating current resistances of the same battery cell are measured by using a plurality of measuring devices 310, 320, and 322. The battery cell measured to calibrate the deviation between the plurality of measuring devices 310, 320, and 322 is hereinafter referred to as a “battery sample” 300. In an embodiment, the battery sample 300 may include a plurality of battery cells.

One of the plurality of measuring devices 310, 320, and 322 is set as a reference measuring device 310. The calibrating apparatus 100 sets the alternating current resistance of the battery sample 300 measured by the reference measuring device 310, as a reference alternating current resistance 330. For example, when the battery sample 300 includes a plurality of battery cells, the reference measuring device 310 measures the alternating current resistance for each of the plurality of battery cells. In addition, the calibrating apparatus 100 may set the reference alternating current resistance 330 by adding up a plurality of alternating current resistances measured by the reference measuring device 310 using a statistical method such as an average. For example, the calibrating apparatus 100 may obtain an average of a plurality of alternating current resistances using an average value (Equation 1), a median value (Equation 2), or an average value using an ignition equation (Equation 3), which are shown as follows:

$$\overline{X} = \frac{1}{N} {\sum }_{i}^{N} {x}_{i} \qquad [ Equation 1 ]$$

$$[ Equation 2 ]$$

$${\overline{X}}_{N} = \frac{{x}_{1} + {x}_{2} + … + {x}_{N}}{N} \qquad [ Equation 3 ]$$

$${\overline{X}}_{N - 1} = \frac{{x}_{1} + {x}_{2} + … + {x}_{N - 1}}{N - 1}$$

$$\frac{N}{N - 1} {\overline{X}}_{N} = \frac{{x}_{1} + {x}_{2} + … + {x}_{N}}{N - 1} = {\overline{X}}_{N - 1} + \frac{xN}{N - 1}$$

$$∴ {\overline{X}}_{N} = \frac{N - 1}{N} {\overline{X}}_{N - 1} + \frac{1}{N} {x}_{N}$$

xᵢ represents an alternating current resistance of each battery cell, and N represents the number of battery cells. For Equation 3, an average value is updated every time a new value is input, thereby requiring less calculation in actual application.

The calibrating apparatus 100 receives measured values of alternating current resistances 340 and 342 of the battery sample 300 from the other measuring devices 320 and 322 than the reference measuring device 310 among the plurality of measuring devices 310, 320, and 322. When the battery sample 300 includes a plurality of battery cells, the other measuring devices 320 and 322 obtain the alternating current resistances of the plurality of battery cells. The calibrating apparatus 100 may obtain the alternating current resistances 340 and 342 of the measuring devices 320 and 322 by adding up the alternating current resistances of the plurality of battery cells measured by the measuring devices 320 and 322 using a statistical method. For example, Equations 1 to 3 above may be applied.

The calibrating apparatus 100 determines a deviation between the reference alternating current resistance 330 of the reference measuring device 310 and each of the alternating current resistances 340 and 342 of the measuring devices 320 and 322. Specifically, the calibrating apparatus 100 obtains a deviation 350 between the first alternating current resistance 340 measured by using the first measuring device 320 and the reference alternating current resistance 330, and obtains a deviation 352 between the second alternating current resistance 342 measured by using the second measuring device 322 and the reference alternating current resistance 330.

For example, the calibrating apparatus 100 may obtain the deviation between the reference alternating current resistance 330 and each of the alternating current resistances 340 and 342 for each frequency of the alternating current voltage applied to the battery. It is assumed that an alternating current resistance of the battery sample 300 measured by the reference measuring device 330 by applying an alternating current voltage of a first frequency to the battery sample 300 is A1, and an alternating current resistance of the battery sample 300 measured by the reference measuring device 330 by applying an alternating current voltage of a second frequency to the battery sample 300 is B1. When an alternating current resistance of the battery sample 300 measured by the first measuring device 320 by applying the alternating current voltage of the first frequency is A2, and an alternating current resistance of the battery sample 300 measured by the first measuring device 320 by applying the alternating current voltage of the second frequency is B2, the calibrating apparatus 100 may obtain each of the deviation (A1-A2) for the first frequency and the deviation (B1-B2) for the second frequency.

The calibrating apparatus 100 stores the deviation between the reference alternating current resistance 330 of the reference measuring device 310 and each of the alternating current resistances 340 and 342 of the measuring devices 320 and 322. Afterwards, when measuring the alternating current resistances of the actual battery cell using at least one or more measuring devices 320 and 322, the calibrating apparatus 100 calibrates the alternating current resistances of the battery cell measured by the corresponding measuring devices 320 and 322 using the previously stored deviations 350 and 352. For example, the first measuring device 320 measures alternating current resistances by applying an alternating current voltage to a first battery cell, and the second measuring device 322 measures alternating current resistances by applying an alternating current voltage to a second battery cell. When obtaining the deviations 350 and 352, the plurality of measuring devices 310, 320, and 322 all measure the alternating current resistances of the same battery sample 300, but during actual measurement, each measuring device 310, 320, and 322 measures different battery cells. The calibrating apparatus 100 calibrates the alternating current resistance of the first battery cell measured by the first measuring device 320 using the previously stored deviation 350 of the first measuring device 320, and calibrates the alternating current resistance of the second battery cell measured by the second measuring device 322 using the previously stored deviation 352 of the second measuring device 322.

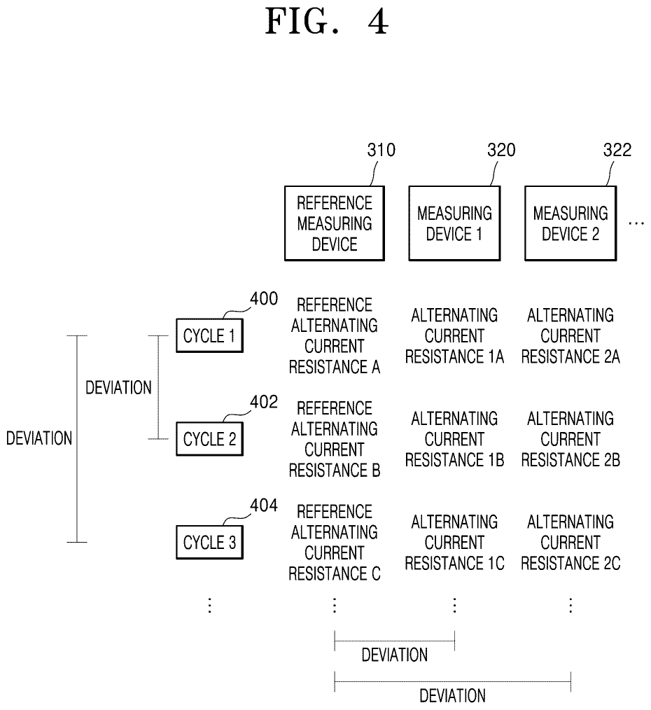

FIG. 4 is a diagram showing an example of a method of calibrating a deviation in alternating current resistance between measuring devices for each cycle according to an embodiment of the present disclosure.

Referring to FIG. 4, the alternating current resistance values of the same battery sample 300 measured the plurality of measuring devices 310, 320, and 322 may vary over time. For example, the reference alternating current resistance of the battery sample 300 measured yesterday by the reference measuring device 310 may be different from the reference alternating current resistance of the same battery sample 300 measured today for various reasons.

In this embodiment, each cycle 400, 402, and 404 refers to an elapsed time during which the deviation between the reference alternating current resistance and the alternating current resistance must be re-established, and does not necessarily refer to a certain time interval. For example, the deviation setting process shown in FIG. 3 may be performed before using the measuring devices 310, 320, and 322 on a daily basis. Alternatively, the deviation setting process of FIG. 3 may be performed before using the measuring devices 310, 320, and 322 in the morning, and the deviation setting process of FIG. 3 may be performed again before using the measuring devices 310, 320, and 322 in the afternoon. Therefore, the cycle may be modified in various ways depending on embodiments.

In a first cycle 400, a reference alternating current resistance A, an alternating current resistance 1A, and an alternating current resistance 2A for the same battery sample are measured using a reference measuring device 310 and a plurality of measuring devices 320 and 322. The calibrating apparatus 100 obtains the deviation between the reference alternating current resistance A and the alternating current resistance 1A in the first cycle 400, and the deviation between the reference alternating current resistance A and the alternating current resistance 2A (i.e., deviation between devices (hereinafter, referred to as “first deviation”)).

When the measuring devices 310, 320, and 322 are used in the second cycle 402, a reference alternating current resistance B, an alternating current resistance 1B, and an alternating current resistance 2B of the battery sample used in the first cycle 400 are measured using the reference measuring device 310 and the plurality of measuring device 320 and 322. The calibrating apparatus 100 obtains the first deviation, which is a deviation between devices, by using the method of FIG. 3. The alternating current resistance of the battery cell (different from the battery sample) measured by each measuring device 320 and 322 may be calibrated by using the first deviation obtained in the second cycle 402. However, since there may be deviations between the reference alternating current resistances in the first cycle 400 and in the second cycle 402, the calibrating apparatus 100 obtains the deviation between the reference alternating current resistance A in the first cycle 400 and the reference alternating current resistance B in the second cycle 402 (i.e., deviation between cycles (hereinafter, referred to as “second deviation”)). In the second cycle 402, alternating current resistances calibrated using the first deviation are calibrated again using the second deviation. In other words, an alternating current resistance of a first battery sample measured by the first measuring device 320 in the second cycle 402 is calibrated by considering the first deviation of the first measuring device 320 determined in the second cycle 402 and the second deviation determined between the reference alternating current resistances in the first cycle 400 and in the second cycle 402.

When using the measuring devices 310, 320, and 322 in a third cycle 404, the calibrating apparatus 100 obtains a first deviation between a reference alternating current resistance C and each of alternating current resistances 1C and 2C in the third cycle 404 and a second deviation between reference alternating current resistances in the first cycle 400 and in the third cycle 404. In addition, the calibrating apparatus 100 calibrates the alternating current resistance of each battery cell measured by each measuring device 320 and 322 in the third cycle 404 using the first deviation and the second deviation.

The above calibration method is expressed in mathematical equation as follows:

$${EIS}_{calibration} ( f ) = {EIS}_{raw} ( f ) + {δ}_{ref - j , device} ( f ) + {δ}_{ref - i , day} ( f ) \qquad [ Equation 4 ]$$

$${δ}_{ref - j , device} = ( f ) ( f )$$

$${δ}_{ref - i , day} ( f ) = ( f ) ( f )$$

EIS_{calibration} (f) represents a value obtained by calibrating the alternating current resistance measured by applying an alternating current voltage of frequency f to the battery cell, EIS_{raw} (f) represents an alternating current resistance measured by applying an alternating current voltage of frequency f to the battery cell using the measuring devices 320 and 322, δ_{ref-j-device} (f) represents the first deviation, and δ_{ref-i.day} (f) represents the second deviation. EIS_{ref device@ith day} (f) refers to a reference alternating current resistance of the battery sample measured by the reference measuring device 310 in the i^{th} cycle, and EIS_{jth device@ith day} (f) refers to an alternating current resistance of the battery sample measured by the measuring devices 320 and 322 in the i^{th} cycle. In addition, EIS_{ref devices@ref day} (f) refers to a reference alternating current resistance of the battery sample measured by the reference measuring device 310 in the first cycle, and EIS_{ref device@ith day} (f) refers to a reference alternating current resistance of the battery sample measured by the reference measuring device 310 in the i^{th} cycle.

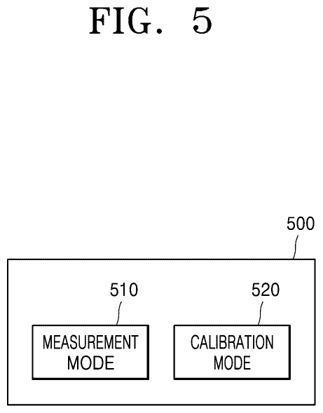

FIG. 5 is a diagram showing an example of a user interface for calibrating a deviation between battery measurement data according to an embodiment of the present disclosure.

Referring to FIG. 5, the calibrating apparatus 100 provides a user interface 500 that allows a user to select a measurement mode 510 or a calibration mode 520. When the user selects the calibration mode 520, the calibrating apparatus 100 receives measured values of the alternating current resistance of the battery sample from the reference measuring device (310 in FIG. 3) and at least one or more general measuring devices (320 and 322 in FIG. 3).

In an embodiment, the reference measuring device and at least one or more measuring devices may be connected to the calibrating apparatus 100 by wire or wirelessly, and may transmit the measured values along with their identification data to the calibrating apparatus 100. In this case, the calibrating apparatus 100 may use the identification data to recognize and store the measured values from which measuring device.

In another embodiment, the calibrating apparatus 100 may provide a user interface that allows the user to select a reference measuring device or a measuring device. The user may select the reference measuring device or the measuring device through the user interface, and may input the alternating current resistance of the battery sample measured by the reference measuring device or the measuring device through the user interface. Alternatively, as the reference measuring device or the measuring device is connected to the calibrating apparatus by wire or wirelessly, the user only needs to select the reference measuring device or the measuring device through the user interface, and an alternating current resistance measurement value measured by the reference measuring device or the measuring device may be automatically transmitted to the calibrating apparatus 100.

The calibrating apparatus 100 uses the alternating current resistances of the battery sample received from the reference measuring device and the general measuring device to determine and store the deviation between the reference alternating current resistance and the alternating current resistance. The calibrating apparatus 100 may determine the deviation between cycles (second deviation) and store the same together, as shown in the example of FIG. 4.

When the user selects the measurement mode 510, the calibrating apparatus 100 calibrates the alternating current resistance of the battery cell measured by the measuring device using the deviation determined in the previous calibration mode 520.

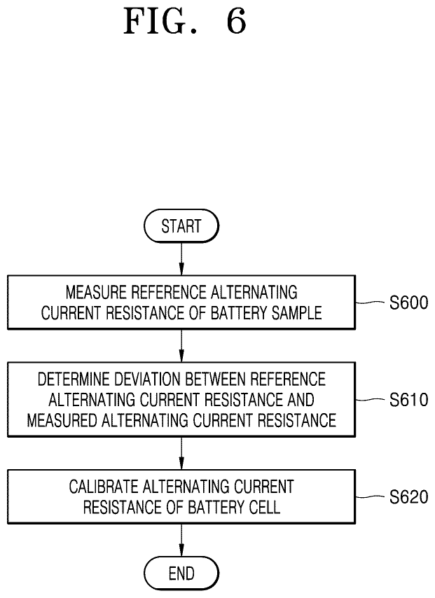

FIG. 6 is a flowchart showing an example of a method of calibrating battery measurement data according to an embodiment of the present disclosure.

Referring to FIG. 6, when the calibrating apparatus 100 receives the alternating current resistance measurement value from the reference measuring device, the calibrating apparatus 100 stores the value as a reference alternating current resistance (S600). When the calibrating apparatus 100 receives the alternating current resistance measurement value of the battery sample from at least one or more measuring devices, the calibrating apparatus 100 determines and stores the first deviation between the reference alternating current resistance and the alternating current resistance of each measuring device (S610). In another embodiment, the calibrating apparatus 100 may determine the second deviation between the reference alternating current resistances for each cycle and store the same together, as shown in FIG. 4.

The calibrating apparatus 100 calibrates the alternating current resistance of the battery cell (different from the battery sample) measured by at least one or more measuring devices using the first deviation (S620). In another embodiment, when the second deviation is determined together, the calibrating apparatus 100 calibrates the alternating current resistance using the first deviation and the second deviation together.

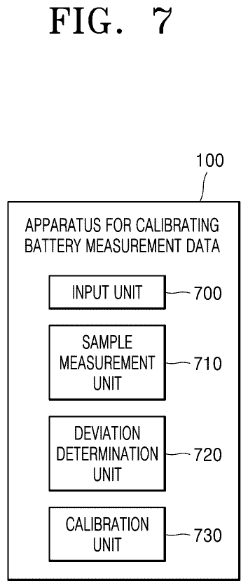

FIG. 7 is a diagram showing the configuration of an example of an apparatus for calibrating battery measurement data according to an embodiment of the present disclosure.

Referring to FIG. 7, the calibrating apparatus 100 includes an input unit 700, a sample measurement unit 710, a deviation determination unit 720, and a calibration unit 730. Depending on embodiments, the input unit 700 may be omitted. In an embodiment, the calibrating apparatus 100 may be implemented as a computing device including memory, a processor, and an input/output device. In this case, each configuration may be implemented as software, loaded into the memory, and then performed by the processor.

The sample measurement unit 710 measures the alternating current resistance of the same battery sample by using a plurality of different measuring devices.

The deviation determination unit 720 sets, as a reference alternating current resistance, the alternating current resistance measured by the measuring device set as the reference measuring device from among the plurality of measuring devices, and determines the first deviation between the reference alternating current resistance and the alternating current resistance measured by each of the other measuring devices. In another embodiment, as shown in the FIG. 4, the deviation determination unit 720 may determine and store the second deviation between the reference alternating current resistance measured by the reference measuring device in the first cycle and the reference alternating current resistance measured by the reference measuring device in a current cycle.

The calibration unit 730 calibrates the alternating current resistance of the battery cell measured by the measuring device using the first deviation. In another embodiment, the calibration unit 730 may calibrate the alternating current resistances of different battery cells measured by a plurality of measuring devices using the first deviation and the second deviation together.

The input unit 700 provides a user interface that allows selection of the measurement mode or the calibration mode. When the calibration mode is selected, the deviation determination unit 720 determines and stores the first deviation and/or the second deviation. When the measurement mode is selected, the calibration unit 730 calibrates the alternating current resistance of the battery cell measured by the measuring device using the previously determined first deviation and/or second deviation.

The present disclosure may also be implemented as computer-readable program code on a computer-readable recording medium. The computer-readable recording medium includes all types of recording devices that store data that can be read by a computer system. Examples of the computer-readable recording medium include ROM, RAM, CD-ROM, magnetic tape, floppy disk, and optical data storage devices. Additionally, the computer-readable recording medium may be distributed across networked computer systems so that computer-readable code can be stored and executed in a distributed manner.

The present disclosure has been examined focusing on embodiments thereof. A person skilled in the art to which the present disclosure pertains may understand that the present disclosure may be implemented in a modified form without departing from the essential characteristics of the present disclosure. Therefore, the disclosed embodiments should be considered from an illustrative rather than a restrictive perspective. The scope of the present disclosure is indicated in claims rather than the above description, and all differences within the equivalent scope should be construed as being included in the present disclosure.

1. A method of calibrating battery measurement data, the method comprising:
measuring alternating current resistances of a same battery sample by using a plurality of different measuring devices;
setting, as a reference alternating current resistance, an alternating current resistance measured by a measuring device set as a reference measuring device from among the plurality of measuring devices, and determining a first deviation between the reference alternating current resistance and each alternating current resistance measured by the other measuring devices; and
storing the first deviation to calibrate alternating current resistances of battery cells measured by the other measuring devices.

2. The method of claim 1, further comprising:
determining a second deviation between the reference alternating current resistance measured by the reference measuring device in a first cycle and the reference alternating current resistance measured by the reference measuring device in a current cycle; and
calibrating the alternating current resistances of different battery cells measured by the plurality of measuring devices using the first deviation and the second deviation for each measuring device.

3. The method of claim 1, further comprising providing a user interface for selecting a measurement mode or a calibration mode,
wherein the first deviation is determined and stored when the calibration mode is selected, and
the alternating current resistances of the battery cells measured by the other measuring devices are calibrated using the previously determined first deviation when the measurement mode is selected.

4. An apparatus for calibrating battery measurement data, the apparatus comprising:
a sample measurement unit configured to measure alternating current resistances of a same battery sample by using a plurality of different measuring devices;
a deviation determination unit configured to set, as a reference alternating current resistance, an alternating current resistance measured by a measuring device set as a reference measuring device from among the plurality of measuring devices, and determine a first deviation between the reference alternating current resistance and each alternating current resistance measured by the other measuring devices; and
a calibration unit configured to calibrate the alternating current resistances of battery cells measured by the other measuring devices using the first deviation.

5. The apparatus of claim 4, wherein the deviation determination unit is configured to determine a second deviation between the reference alternating current resistance measured by the reference measuring device in a first cycle and the reference alternating current resistance measured by the reference measuring device in a current cycle, and
the calibration unit is configured to calibrate the alternating current resistances of different battery cells measured by the plurality of measuring devices using the first deviation and the second deviation.

6. The method of claim 4, further comprising an input unit configured to provide a user interface for selecting a measurement mode or a calibration mode,
wherein the first deviation is determined and stored when the calibration mode is selected, and
the alternating current resistances of the battery cells measured by the other measuring devices are calibrated using the previously determined first deviation when the measurement mode is selected.

7. A computer-readable recording medium recording a computer program for performing the method described in claim 1.
